(19) United States
(12) Patent Application Publication
(10) Pub. No.: US 2015/0091076 A1
(43) Pub. Date: Apr. 2, 2015

(54) ISOLATION FORMATION FIRST PROCESS SIMPLIFICATION

(71) Applicant: Macronix International Co. Ltd., Hsinchu (TW)

(72) Inventor: Guan-Ru Lee, Kaohsiung City (TW)

(21) Appl. No.: 14/044,593

(22) Filed: Oct. 2, 2013

(51) Int. Cl. H01L 21/8234; H01L 29/792; H01L 27/115

(52) U.S. Cl. CPC H01L 21/823481; H01L 27/1157; H01L 29/792
USPC 257/324; 438/424

(57) ABSTRACT

A method for manufacturing a memory device includes providing a substrate having a plurality of active layers, forming a plurality of holes through the plurality of active layers including a first row of holes and a second row of holes, and filling the plurality of holes with an isolation material. The method includes etching the plurality of active layers to form first and second sets of interdigitated stacks of active strips, where the first set includes strips extending from pads in a first stack of pads and terminating at isolation strips remaining from corresponding filled holes in the first row, and the second set includes strips extending from pads in a second stack of pads and terminating at isolation strips remaining from corresponding filled holes in the second row.

### BACKGROUND

1. Field of the Invention

The present invention relates to three-dimensional (3D) memory devices. In particular, embodiments according to the present invention provide a method for manufacturing bit lines and word lines in such memory devices, and a memory structure that can be made using the method.

2. Description of Related Art

High density memory devices are being designed that comprise arrays of flash memory cells, or other types of memory cells. In some examples, the memory cells comprise thin film transistors which can be arranged in three dimensional (3D) architectures.

In one example, a 3D memory device includes a plurality of stacks of strings of memory cells. The stacks include active strips separated by insulating material. The 3D memory device includes an array including a plurality of word lines structures, a plurality of string select structures, and ground select lines, arranged orthogonally over the plurality of stacks. Memory cells including charge storage structures are formed at cross-points between side surfaces of the active strips in the plurality of stacks and the word lines structures.

The 3D memory device is characterized by multiple planes, each of which can include a planar array of active strips. Active strips in a plane can terminate at one end at a contact pad, and at another end at a source line. At either end, active strips can have irregular and discontinuous patterns. Such patterns present challenges for manufacturing processes including etching processes for active strips. Furthermore, patterns for string select gate structures are isolated between adjacent stacks, while patterns for word lines are not isolated between adjacent stacks. Thus, it can be complicated for an etch process to form both word lines and string select gate structures due to different patterns for word lines and string select gate structures.

It is desirable to improve manufacturing processes for 3D memory devices that can result in higher reliability and lower costs.

### SUMMARY

A method for manufacturing a semiconductor device includes providing a substrate having a plurality of active layers, forming a plurality of holes through the plurality of active layers, and filling the plurality of holes with an isolation material such as oxide seals to form filled holes. The plurality of holes is positioned in the plurality of active layers such that a plurality of stacks of active strips can be formed in the plurality of active layers after the filling, and be terminated at the plurality of holes filled with the isolation material.

In one embodiment, the plurality of holes can be configured in a row. A mask can be used to define a plurality of parallel lines, including lines that cross over respective filled holes in the plurality of holes. The plurality of active layers and the filled holes can be etched using a first etch process, to form the plurality of stacks of active strips terminating with strips of isolation material where the lines crossed over the respective holes.

In an alternative embodiment, the plurality of holes can be configured in a first row and a second row. A mask can be used to define a plurality of parallel lines, including a first subset of lines that cross over respective filled holes in the first row, and a second subset of lines that cross over respective filled holes in the second row. The plurality of active layers and the filled holes can be etched using a first etch process, to form the plurality of stacks of active strips including a first set of stacks terminating with strips of isolation material where the lines crossed over the respective holes in the first row of holes, and a second set of stacks terminating with strips of isolation material where the lines crossed over the respective holes in the second row of holes. Select gate structures can be formed over stacks of active strips in the first set of stacks between strips of isolation material at which stacks in the second set of stacks terminate.

In another embodiment, the plurality of holes can be configured in a first row, and a plurality of conductive pillars can be configured in a second row. A mask can be used to define a plurality of parallel lines, including lines that cross over respective filled holes in the first row and respective conductive pillars in the second row. The plurality of active layers, the conductive pillars and the filled holes can be etched using a first etch process, to form the plurality of stacks of active strips including strips of more narrow conductive pillars and terminating at strips of isolation material where the lines crossed over the respective holes and conductive pillars.

The plurality of active layers and the isolation material in the plurality of holes can be etched using a first etch process, to form the plurality of stacks of active strips, and a plurality of isolation strips aligned with the stacks. The substrate can have a plurality of spaced-apart pillars of a first conductor material connecting the plurality of active layers. The plurality of spaced-apart pillars can be etched using the first etch process, to form a plurality of more narrow conductive pillars aligned with the stacks and between a first end of the plurality of active strips and the plurality of isolation strips. The plurality of active layers can be etched using the first etch process, to form stacks of contact pads terminating the plurality of active strips at a second end of the plurality of active strips.

A body of conductor material can be formed by depositing a second conductor material over the substrate. The body of conductor material can be etched using a second etch process, to remove the second conductor material from areas defining patterns for the plurality of active strips, the plurality of source lines, the plurality of isolation strips, the stacks of pads, word lines, ground select lines and string select gate structures. The body of conductor material can be etched using a third etch process, to form the word lines, the ground select lines and the string select gate structures over the plurality of stacks. A string select gate structure over a particular stack in the plurality of stacks is isolated from string select gate structures over adjacent stacks in the plurality of stacks.

A layer of memory material can be formed on side walls of the active strips in the plurality of stacks before the body of conductor material is formed over the substrate.

An integrated circuit device made according to the method is also provided.

Other aspects and advantages of the present invention can be seen on review of the drawings, the detailed description and the claims, which follow.

### BRIEF DESCRIPTION OF THE DRAWINGS

FIG. 1 is a perspective illustration of a three-dimensional (3D) NAND-flash memory device.

FIG. 1A illustrates a section of the memory device shown in FIG. 1, including an isolation strip between a source line and a stack of contact pads.

FIGS. 2 through 7 illustrate a manufacturing process for the memory device in FIG. 1 in one embodiment.

FIGS. 8A-8C illustrate a cross-sectional view of the memory device during a manufacturing process.

FIG. 9 is a simplified process flow of an example of a method for manufacturing a memory device.

FIG. 10 is a simplified block diagram of an integrated circuit memory device according to an embodiment.

### DETAILED DESCRIPTION

A detailed description of various embodiments is described with reference to the Figures. The following description will typically be with reference to specific structural embodiments and methods. It is to be understood that there is no intention to limit the invention to the specifically disclosed embodiments and methods but that the invention may be practiced using other features, elements, methods and embodiments. Preferred embodiments are described to illustrate the present invention, not to limit its scope, which is defined by the claims. Those of ordinary skill in the art will recognize a variety of equivalent variations on the description that follows. Like elements in various embodiments are commonly referred to with like reference numerals.

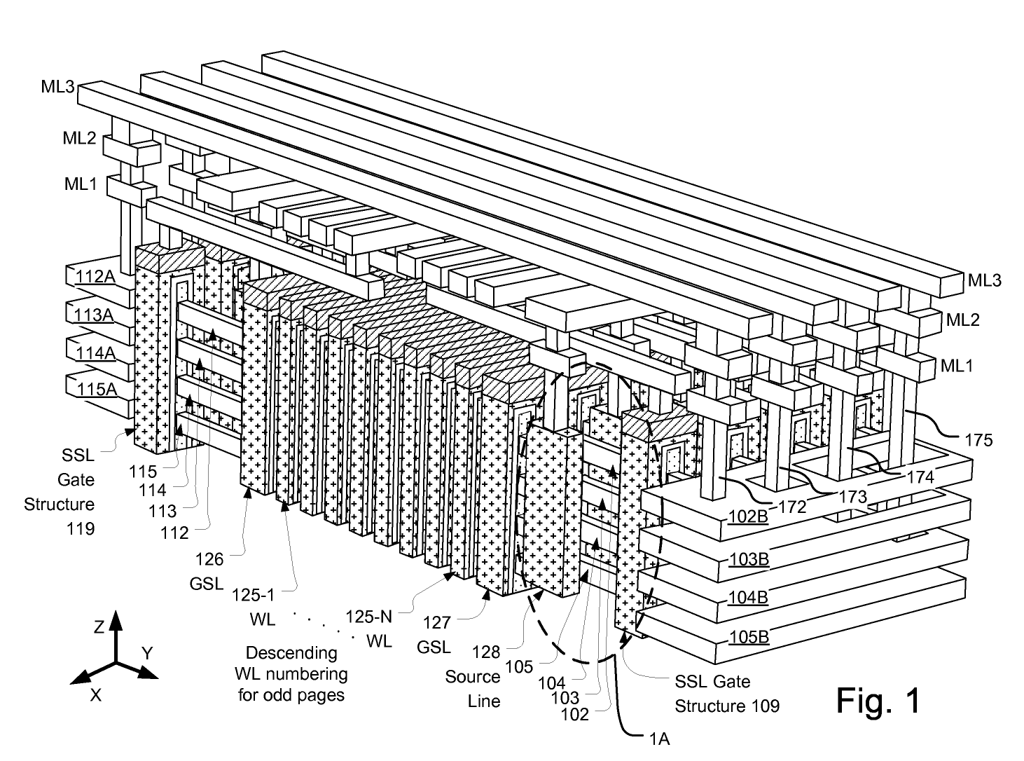

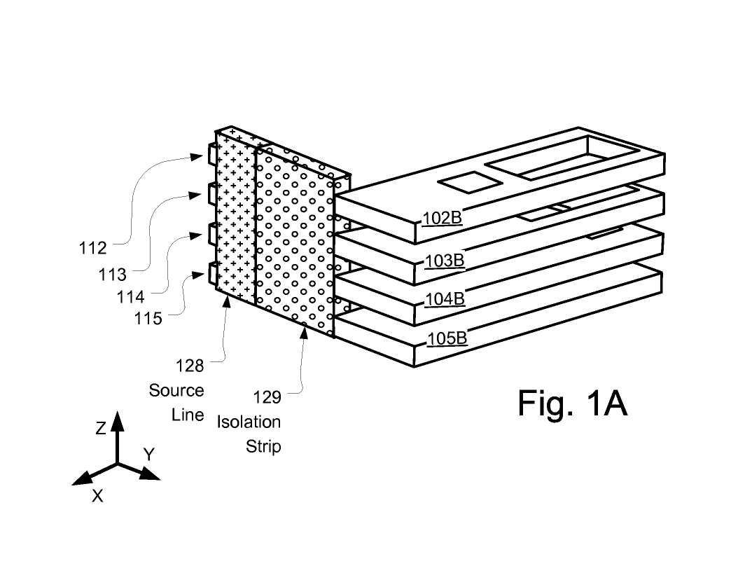

FIG. 1 is a perspective illustration of a three-dimensional (3D) NAND-flash memory device. The device illustrated in FIG. 1 includes a plurality of stacks of active strips alternating with insulating strips. Insulating material is removed from the drawing to expose additional structure. For example, insulating strips are removed between the active strips in the stacks, and are removed between the stacks of active strips. This structure is described herein in some detail, as an example of a three-dimensional (3D) memory array which can be manufactured on a semiconductor substrate, in combination with peripheral circuits on the substrate (not shown). Other multilayer circuit structures can also be formed using the technology described herein.

In the example shown in FIG. 1, a multilayer array is formed on an insulating layer, and includes a plurality of word lines 125-1 WL through 125-N WL conformal with the plurality of stacks. The plurality of stacks includes active strips 112, 113, 114, and 115 in multiple planes. Active strips in the same plane are electrically coupled together by contact pads (e.g. 102B).

A stack of contact pads 112A, 113A, 114A, and 115A terminate active strips, such as the active strips 112, 113, 114, and 115 in the plurality of stacks. As illustrated, these contact pads 112A, 113A, 114A, and 115A are electrically connected to different bit lines for connection to decoding circuitry to select planes within the array. These contact pads 112A, 113A, 114A, and 115A can be patterned at the same time that the plurality of stacks is defined.

A stack of contact pads 102B, 103B, 104B, and 105B terminate active strips, such as active strips 102, 103, 104, and 105. As illustrated, interlayer connectors 172, 173, 174, 175 electrically connect contact pads 102B, 103B, 104B, and 105B to different bit lines in metal layers, such as a metal layer ML3, for connection to decoding circuitry to select planes within the array. The stack of contact pads 102B, 103B, 104B, and 105B can be patterned at the same time that the plurality of stacks is defined.

Any given stack of active strips is coupled to either the stack of contact pads 112A, 113A, 114A, and 115A, or the stack of contact pads 102B, 103B, 104B, and 105B, but not both. The stack of active strips 112, 113, 114, and 115 is terminated at one end by the stack of contact pads 112A, 113A, 114A, and 115A, passes through SSL gate structure 119, ground select line GSL 126, word lines 125-1 WL through 125-N WL, ground select line GSL 127, and is terminated at the other end by source line 128. The stack of active strips 112, 113, 114, and 115 does not reach the stack of contact pads 102B, 103B, 104B, and 105B.

The stack of active strips 102, 103, 104, and 105 is terminated at one end by the stack of contact pads 102B, 103B, 104B, and 105B, passes through SSL gate structure 109, ground select line GSL 127, word lines 125-N WL through 125-1 WL, ground select line GSL 126, and is terminated at the other end by a source line (obscured by other parts of the figure). The stack of active strips 102, 103, 104, and 105 does not reach the stack of contact pads 112A, 113A, 114A, and 115A.

A layer of memory material is disposed in interface regions at cross-points between surfaces of the active strips 112-115 and 102-105 and the plurality of word lines 125-1 WL through 125-N WL. In particular, the layer of memory material is formed on side walls of the active strips in the plurality of stacks. Ground select lines GSL 126 and GSL 127 are conformal with the plurality of stacks, similar to the word lines.

Every stack of active strips is terminated at one end by contact pads and at the other end by a source line. For example, the stack of active strips 112, 113, 114, and 115 is terminated at one end by contact pads 112A, 113A, 114A, and 115A, and terminated on the other end by a source line 128. At the near end of the figure, every other stack of active strips is terminated by the contact pads 102B, 103B, 104B, and 105B, and every other stack of active strips is terminated by a separate source line. At the far end of the figure, every other stack of active strips is terminated by the contact pads 112A, 113A, 114A, and 115A, and every other stack of active strips is terminated by a separate source line.

Bit lines and string select gate structures are formed at the metals layers ML1, ML2, and ML3. Bit lines are coupled to a plane decoder (not shown). String select gate structures are coupled to a string select line decoder (not shown).

The ground select lines GSL 126 and 127 can be patterned during the same step that the word lines 125-1 WL through 125-N WL are defined. Ground select devices are formed at cross-points between surfaces of the plurality of stacks and ground select lines GSL 126 and 127. The SSL gate structures 119 and 109 can be patterned during the same step in which the word lines 125-1 WL through 125-N WL are defined. String select devices are formed at cross-points between surfaces of the plurality of stacks and string select (SSL) gate structures 119 and 109. These devices are coupled to decoding circuitry for selecting the strings within particular stacks in the array.

FIG. 1A illustrates a section of the memory device shown in FIG. 1, as indicated by the dotted oval 1A in FIG. 1. The section includes an isolation strip 129 between the source line 128 and a stack of contact pads including 102B, 103B, 104B, and 105B. The isolation strip 129 can be a hole filled with an isolation material such as oxide. The source line 128 terminates a stack of active strips including active strips 112-115 at a first end of the stack. The stack of contact pads 102B, 103B, 104B, and 105B terminates an adjacent stack of active strips including active strips 102-105 at a second end of the adjacent stack. The active strips 102-105 are shown in FIG. 1.

The memory device includes a first row and a second row of isolation strips, and a first set and a second set of interdigitated stacks of active strips. The first set includes active strips (e.g. 112-115) extending from contact pads in a first stack of contact pads (e.g. 112A-115A), and terminating at corresponding isolation strips in the first row of isolation strips (e.g. 129). The second set includes active strips (e.g. 102-105) extending from contact pads in a second stack of contact pads (e.g. 102B-105B), and terminating at corresponding isolation strips in the second row of isolation strips (not shown). A source line (e.g. 128) is aligned with a stack of active strips (e.g. 112-115) in the Y direction, and between the active strips (e.g. 112-115) and an isolation strip (e.g. 129). The isolation strip 129 can be an example of an isolation strip in either the first row of isolation strips or the second row of isolation strips.

FIGS. 2 through 7 illustrate a manufacturing process for the memory device in FIG. 1 in one embodiment. As an example, FIG. 2 illustrates one active layer 210 in a plurality of active layers in a partially manufactured semiconductor substrate for the memory device. Each active layer is in an X-Y plane including an X direction perpendicular to a Y direction, while the plurality of active layers is arranged in a Z direction perpendicular to the X-Y plane. The substrate has a plurality of spaced-apart pillars of a first conductor material extending through and connecting the plurality of active layers in the Z direction. As shown in the example of the active layer 210, the plurality of spaced-apart pillars are arranged in a first row including a first pillar 221, and in a second row including a second pillar 222. The first row and the second row are arranged along the X direction in the X-Y plane.

The active layers (e.g. 210) can be made using intrinsic or lightly doped polysilicon while the pillars (e.g. 221, 222) can be made using relatively heavily doped n+-type polysilicon or other conductive material selected for conductivity and compatibility with the manufacturing processed utilized. The pillars (e.g. 128, FIGS. 1 and 1A) can be formed with an etch process, and then the active layers interleaved with insulation layers can be formed with a fill-in process.

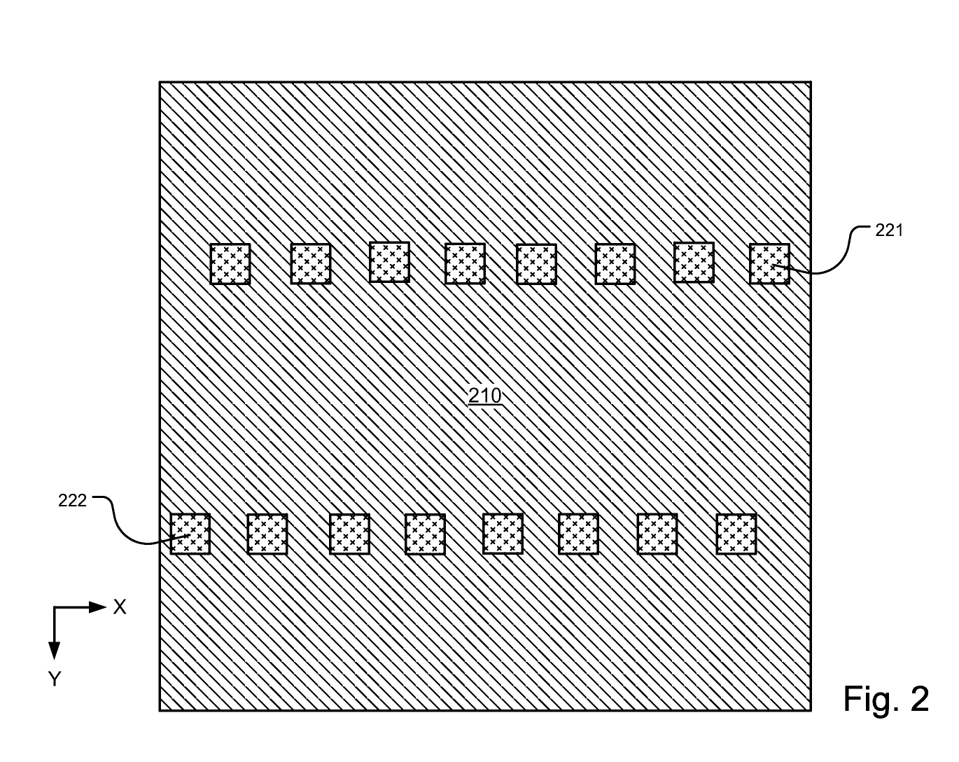

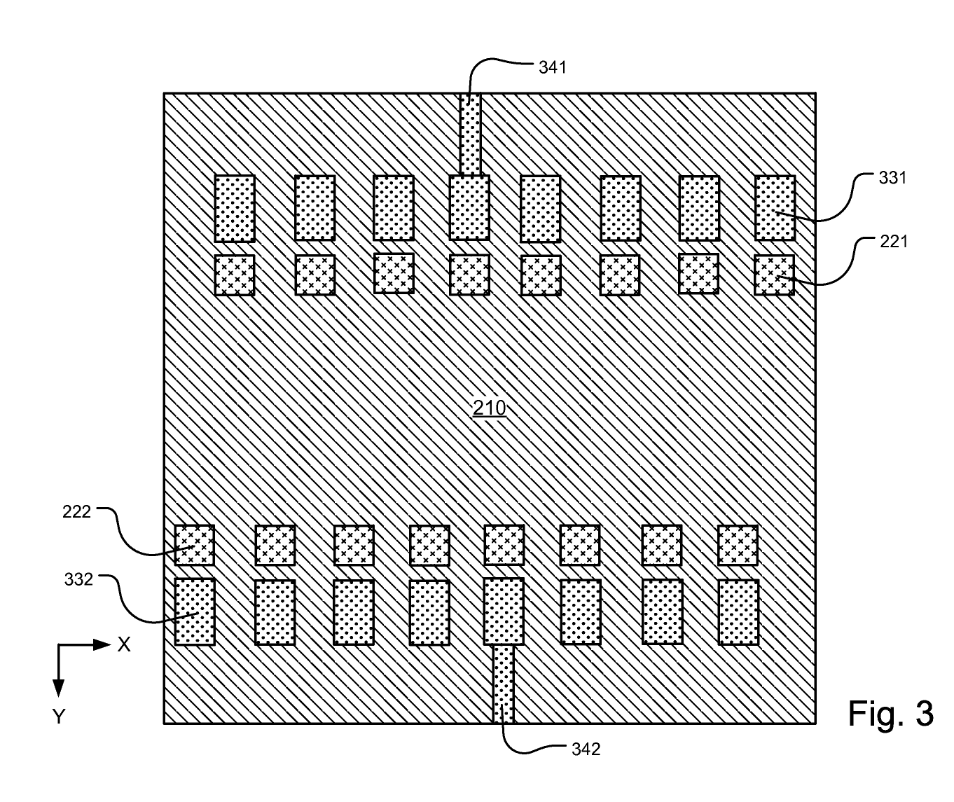

FIG. 3 shows the device at a subsequent stage in the manufacturing process. In the process, a plurality of isolation holes is first formed by etching through the plurality of active layers, and then filled with an isolation material such as silicon oxide or silicon nitride. The plurality of holes is positioned in the plurality of active layers such that a plurality of stacks of active strips can be formed in the plurality of active layers after the holes are filled with the isolation material, and be terminated at the plurality of holes.

In the embodiment illustrated, for the formation of interdigitated active strips, the plurality of holes are arranged in a first row including a first hole 331, and in a second row including a second hole 332. The first row of holes and the second row of holes are arranged along the X direction in the X-Y plane. The first row of holes is aligned with the first row of conductive pillars in the Y direction, and the second row of holes is aligned with the second row of conductive pillars in the Y direction. For example, the first hole 331 in the first row of holes is aligned with the first conductive pillar 221 in the first row of conductive pillars, and the second hole 332 in the second row of holes is aligned with the second conductive pillar 222 in the second row of conductive pillars. In other embodiments, the active strips may not be interdigited for example, and the isolation holes may be formed in only one row.

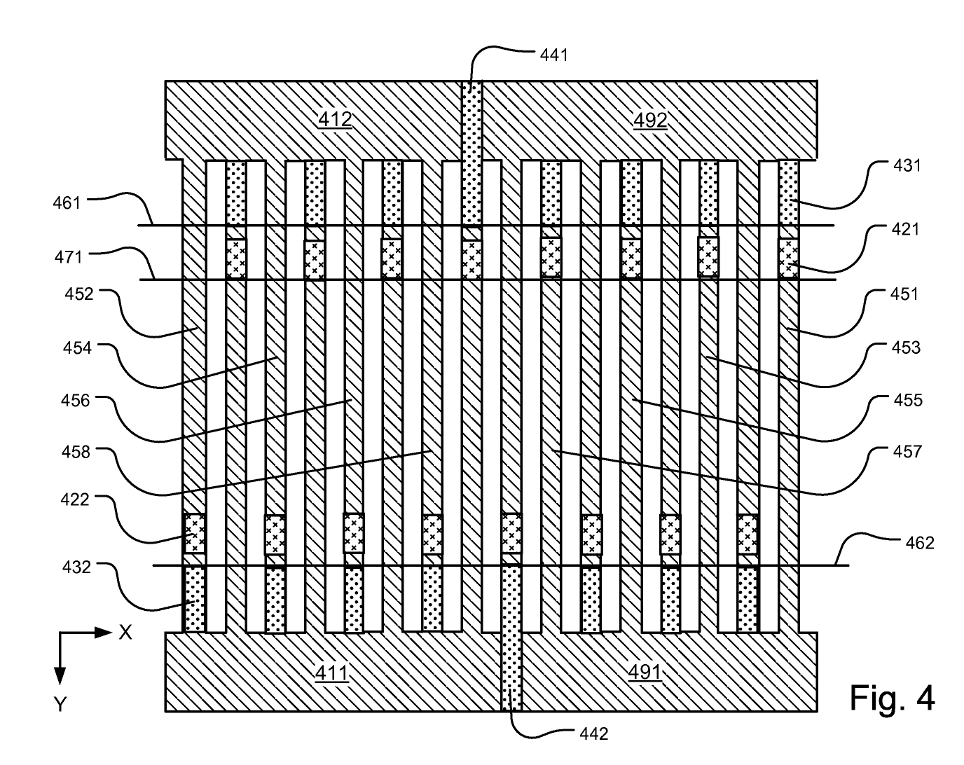

Although the plurality of holes are illustrated in layout view showing one active layer (e.g. 210), each of the holes is as deep as the plurality of active layers in the Z direction perpendicular to the X-Y plane. The holes filled with the isolation material (e.g. 331, 332) are used to form isolation strips at one end of active strips (e.g. 112-115, FIG. 1). The holes have critical dimension larger than the width of the active strips (e.g. 112-115, FIG. 1; 451, 452, FIG. 4) plus a process overlay window to provide better isolation.

Bit line pad cuts (e.g. 341, 342) can be made to divide the device into blocks of stacks of active strips such that layers of active strips in the blocks can support respective bit lines via contact pads in the respective blocks. For instance, a block with four layers of active strips can support four bit lines, while another block with four layers of active strips can support four other bit lines. In one embodiment, the bit line pad cuts can be made in the same process to etch the plurality of isolation holes, and then to fill the holes with the isolation material such as silicon oxide or silicon nitride. The bit line pad cuts can be filled with the same isolation material as the plurality of isolation holes. Although the bit line pad cuts are illustrated in layout view showing one active layer (e.g. 210), each of the bit line pad cuts is as deep as the plurality of active layers in the Z direction perpendicular to the X-Y plane.

FIG. 4 illustrates the device after etching the plurality of active layers using a first etch process. Bit line pad cuts (e.g. 441 and 442) support dividing the structure into two blocks. For instance, a first block of the two blocks includes a first contact pad 411 and a second contact pad 412, while a second block of the two blocks includes a first contact pad 491 and a second contact pad 492. Each of the first block and the second block can have first and second sets of interdigitated stacks of active strips. Within the first block, active strips in the first set extend from the first contact pad 411, while active strips in the second set extend from the second contact pad 412. Within the second block, active strips in the first set extend from the first contact pad 491, while active strips in the second set extend from the second contact pad 492. The bit line pad cuts (e.g. 441, 442) can support formation of repeating block structures in a large array to the left and right of a particular block.

In one embodiment, as illustrated in FIG. 4, the plurality of holes can be configured in a row. For instance, the plurality of holes are arranged in a row including a first hole 331 (FIG. 3). A mask can be used to define a plurality of parallel lines, including lines that cross over respective filled holes in the plurality of holes (e.g. 461). The plurality of active layers (e.g. 210, FIG. 3) and the filled holes (e.g. 331, FIG. 3) can be etched using a first etch process, to form the plurality of stacks of active strips (e.g. 451) terminating with strips of isolation material where the lines (e.g. 461) crossed over the respective holes (e.g. 431).

In an alternative embodiment, the plurality of holes can be configured in a first row and a second row. For instance, the plurality of holes are arranged in a first row including a first hole 331 (FIG. 3), and in a second row including a second hole 332 (FIG. 3). A mask can be used to define a plurality of parallel lines, including a first subset of lines that cross over respective filled holes in the first row (e.g. 461), and a second subset of lines that cross over respective filled holes in the second row (e.g. 462). The plurality of active layers (e.g. 210, FIG. 3) and the filled holes (e.g. 331, 332 FIG. 3) can be etched using a first etch process, to form the plurality of stacks of active strips (e.g. 451, 452) including a first set of stacks terminating with strips of isolation material where the lines (e.g. 461) crossed over the respective holes in the first row of holes (e.g. 431), and a second set of stacks terminating with strips of isolation material where the lines (e.g. 462) crossed over the respective holes in the second row of holes (e.g. 432).

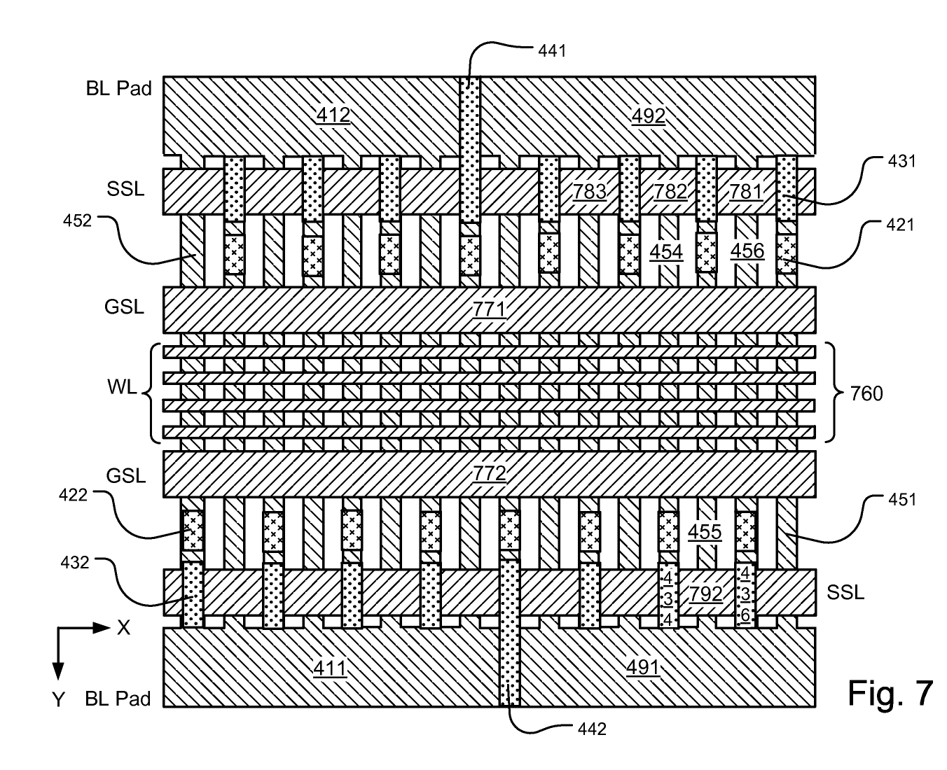

Furthermore, as illustrated in the example of FIG. 7, select gate structures (e.g. 792) can be formed over stacks of active strips in the first set of stacks (e.g. 455) between strips of isolation material (e.g. 434, 436) at which stacks in the second set of stacks (e.g. 454, 456) terminate.

In another embodiment, the plurality of holes can be configured in a first row, and a plurality of conductive pillars can be configured in a second row. For instance, the plurality of holes are arranged in a first row including a first hole 331 (FIG. 3), and the plurality of conductive pillars can be configured in a second row including a conductive pillar 221 (FIG. 3). A mask can be used to define a plurality of parallel lines, including lines that cross over respective filled holes in the first row (e.g. 461) and respective conductive pillars in the second row (e.g. 471). The plurality of active layers (e.g. 210, FIG. 3), the conductive pillars (e.g. 221, 222, FIG. 3) and the filled holes (e.g. 331, 332 FIG. 3) can be etched using a first etch process, to form the plurality of stacks of active strips (e.g. 451, 452) including strips of more narrow conductive pillars (e.g. 421, 422) and terminating at strips of isolation material (e.g. 431, 432) where the lines crossed over the respective holes and conductive pillars (e.g. 461, 471).

As illustrated in the example of FIG. 4, a plurality of stacks of active strips is formed by the first etch process. The plurality of stacks of active strips is formed in first and second sets of interdigitated stacks of active strips. As shown in the example illustrated in FIG. 4, the first set includes active strips 451, 453, 455, and 457, while the second set includes active steps 452, 454, 456, and 458. Active strips in the first set alternate with the active strips in the second set.

A plurality of isolation strips is formed by the first etching process from the first row of holes and the second row of holes filled with the isolation material (e.g. 331, 332, FIG. 3). The plurality of isolation strips is aligned with the plurality of stacks of active strips in the Y direction. The plurality of isolation strips is formed in first and second sets of isolation strips, corresponding to the first and second sets of interdigitated stacks of active strips. For instance, isolation strip 431 in the first set of isolation strips is aligned with the active strip 451 in the first set of active strips, while isolation strip 432 in the second set of isolation strips is aligned with the active strip 452 in the second set of active strips.

A plurality of more narrow conductive pillars is formed by the first etching process from the first row of conductive pillars and the second row of conductive pillars (e.g. 221, 222, FIG. 3). The plurality of more narrow conductive pillars is aligned with the plurality of stacks of active strips in the Y direction. The plurality of more narrow conductive pillars includes first and second sets of more narrow conductive pillars, corresponding to the first and second sets of interdigitated stacks of active strips. For instance, conductive pillar 421 in the first set of more narrow conductive pillars is aligned with the active strip 451 in the first set of active strips, while conductive pillar 422 in the second set of more narrow conductive pillars is aligned with the active strip 452 in the second set of active strips. For instance, conductive pillar 421 is more narrow than corresponding conductive pillar 221 (FIG. 3) from which conductive pillar 421 is formed. Likewise, conductive pillar 422 is more narrow than conductive pillar 222 (FIG. 3) from which conductive pillar 421 is formed. More narrow conductive pillars in the plurality of more narrow conductive pillars are formed between a first end of the plurality of active strips and the plurality of isolation strips.

Stacks of contact pads are formed by the first etching process from the plurality of active layers (e.g. 210, FIG. 3). For instance, a first contact pad 411 in a first stack of contact pads (e.g. 112A-115A, FIG. 1) terminates the first set of active strips including active strips 451, 453, 455, and 457 at a second end of the active strips, while a second contact pad 412 in a second stack of contact pads (e.g. 102B-105B, FIG. 1) terminates the second set of active strips including active steps 452, 454, 456, and 458 at a second end of the active strips.

As illustrated in FIG. 4, the interdigitated stacks of active strips have irregular and discontinuous ends at contact pads and at source lines, manufacturing of such features can be complex. Because the isolation material in the plurality of holes and the plurality of conductive pillars are formed before the first etch process, the first etch process can use a regular pattern to form a plurality of stacks of active strips, a plurality of isolation strips, a plurality of source lines, and stacks of contact pads, thus simplifying the manufacturing process for active strips.

FIG. 5 illustrates the device after forming a body of conductor material (e.g. 510) by depositing a second conductor material over the substrate. The body of conductor material can be used to form word lines (e.g. 125-1 WL . . . 125-N WL, FIG. 1), ground select lines (e.g. 126 GSL, 127 GSL, FIG. 1), and string select gate structures (119, 109, FIG. 1) with further processing.

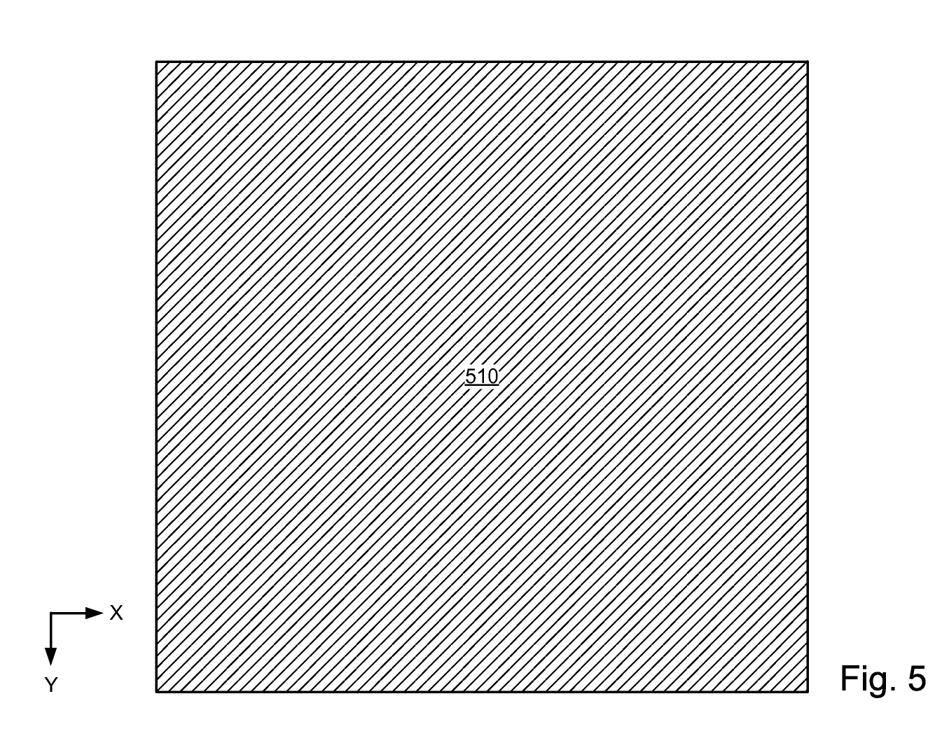

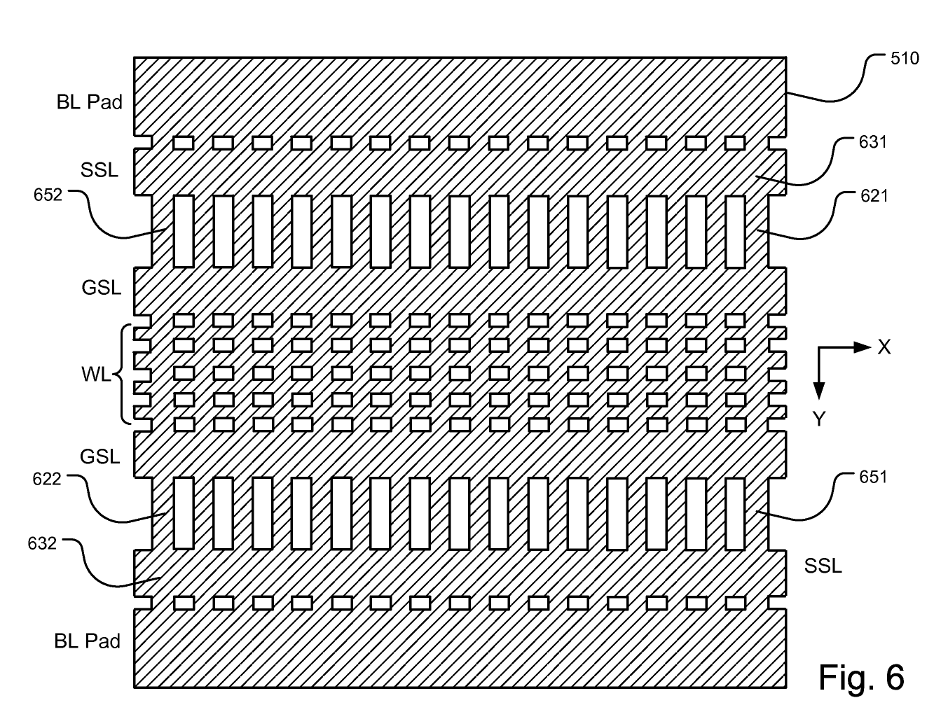

FIG. 6 illustrates the device after the body of conductor material 510 is etched using a second etch process. The second etch process can use a hole-type pattern that includes patterns for the plurality of active strips (e.g. 651, 652), the plurality of source lines (e.g. 621, 622), the plurality of isolation strips (e.g. 631, 632), the stacks of pads (BL pad), word lines (WL), ground select lines (GSL) and string select gate structures (SSL). The second etch process removes the second conductor material from areas defining the patterns in the hole-type pattern through multiple planes in the Z direction perpendicular to the X-Y plane. The multiple planes correspond to the plurality of active layers in the substrate, and are described in connection with FIG. 1. The second etch process leaves portions of the body of conductor material 510 for at least forming word lines (WL), ground select lines (GSL) and string select gate structures (SSL).

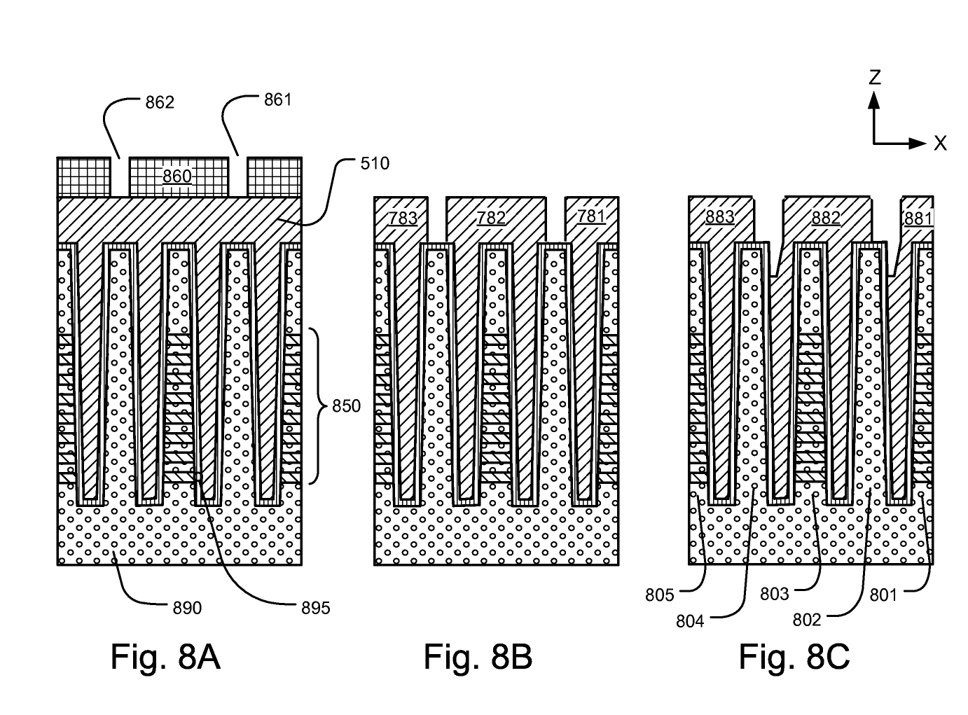

The plurality of isolation strips, already formed using the first etch process (FIG. 4), provides isolation between adjacent SSL (string select line) gate structures (e.g. 109, 119, FIG. 1). Consequently the second etch process (FIG. 6) is simplified because the second etch process does not need to create holes to form isolation between adjacent SSL gate structures. See, FIGS. 8A-8C described below.

FIG. 7 illustrates the device after the body of conductor material 510 is etched using a third etch process. The third etch process is a line type etch and stops on top of the stacks of active strips, and therefore can be a more shallow etch than the hole type etch used for the second etch. The second etch process leaves some remaining portions of the body of conductor material 510. For instance, the remaining portions include portions of the body of conductor material 510 that are over the stacks of pads (BL pad), over the plurality of source lines, over the plurality of isolation strips, and between the patterns for the word lines. The third etch process etches the remaining portions of the body of conductor material 510 to form the word lines (e.g. 760), the ground select lines (e.g. 771, 772) and the string select gate structures (e.g. 781, 782. 783) over the plurality of stacks. A string select gate structure (e.g. 782) over a particular stack in the plurality of stacks is isolated from string select gate structures (e.g. 783, 781) over adjacent stacks in the plurality of stacks.

The third etch process also removes the remaining portions of the body of conductor material 510 that are not portions of the word lines, the ground select lines, and the string select gate structures. The remaining portions removed include the portions over the stacks of pads (BL pad), over the plurality of source lines, and over the plurality of isolation strips.

FIG. 8A illustrates a cross-sectional view in the X-Z plane of the memory device during the third etch process as described in connection with FIG. 7. The cross-sectional view is taken along a row of string select gate structures including 781-783 in FIG. 7. An etch mask 860 including openings 861 and 862 is deposited over the body of conductor material 510. The etch mask 860 is patterned to define the pattern of the plurality of string select gate structures for the stacks. A plurality of stacks of active strips (e.g. 850) alternating with insulating material (e.g. 890) is formed in the substrate. A layer of memory material (e.g. 895) is deposited over the plurality of stacks of active strips, and at least on side walls of the active strips before the body of conductor material 510 is formed over the substrate.

Depending upon the implementation, layer 895 of memory material can comprise multilayer dielectric charge storage structures. For example, a multilayer dielectric charge storage structure includes a tunneling layer including a silicon oxide, a charge trapping layer comprising a silicon nitride and a blocking layer comprising a silicon oxide. In other implementations, layer 895 of memory material can include only a charge trapping layer without the tunneling layer or the blocking layer.

In other embodiments, different programmable resistance memory materials can be used as the memory material, including metal oxides like tungsten oxide on tungsten or doped metal oxide, and others. Various kinds of programmable metallization material can also be implemented as the memory material to form programmable metallization cells (PMC). Some of such materials can form devices that can be programmed and erased at multiple voltages or currents, and can be implemented for operations storing multiple bits per cell.

FIG. 8B illustrates the device after etching to form isolated string select gate structures in the plurality of string select gate structures, such that a string select gate structure over a particular stack in the plurality of stacks is isolated from string select gate structures over adjacent stacks in the plurality of stacks. For example, a string select gate structure (e.g. 782) over a particular stack in the plurality of stacks is isolated from string select gate structure (e.g. 781, 783) over adjacent stacks in the plurality of stacks. The etch mask 860 is subsequently removed. In FIG. 8B, a string select gate structure (e.g. 782) is substantially centered on a corresponding stack of active strips, such that the string select gate structure is substantially equidistant from adjacent stacks. FIG. 8C illustrates a scenario where a string select gate structure (e.g. 882) is less centered (as a result of a slightly misaligned mask 860) on a corresponding stack of active strips (e.g. 781, 783. Even with such misalignment, the string select gate structures are still isolated from each other by the isolation strips 802 and 804.

As described here, the plurality of stacks of active strips in the memory device is formed in first and second sets of interdigitated stacks of active strips. The first set includes strips extending from contact pads in a first stack of contact pads and terminating at corresponding isolation strips in a first row of isolation strips, and the second set includes strips extending from bit lines pads in a second stack of contact pads and terminating at corresponding isolation strips in a second row of isolation strips.

As illustrated in the cross-sectional view in FIGS. 8A-8C, stacks of active strips from the first set of interdigitated stacks (e.g. 801, 803, 805) alternate with isolation strips terminating stacks of active strips from the second set of interdigitated stacks (e.g. 802, 804). Consequently, the isolation strips already formed for one set of interdigitated stacks provides better tolerance for misalignment between string select gate structure and corresponding active strips for another set of interdigitated stacks.

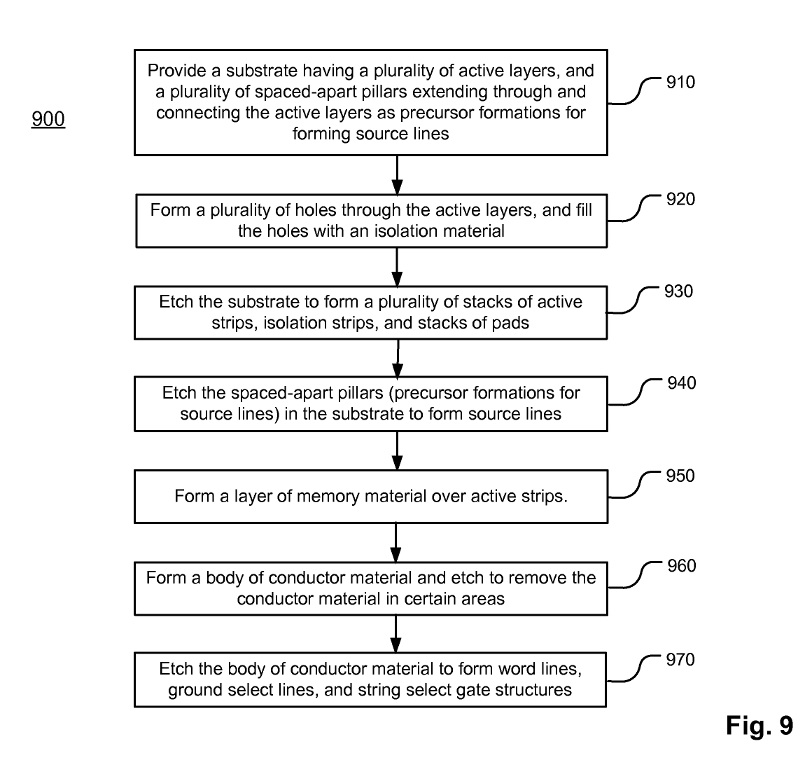

FIG. 9 is a simplified process flow 900 of an example of a method for manufacturing a memory device. The process steps shown in FIG. 9 begin at the stage shown in FIG. 2 for example, with providing a substrate that has a plurality of active layers (910). The substrate also has a plurality of spaced-apart pillars of a first conductor material (e.g. 221, 222, FIG. 2) extending through and connecting the plurality of active layers. The plurality of spaced-apart pillars are precursor formations for forming source lines and are arranged in a first row and a second row.

Then, a plurality of holes is formed by etching through the plurality of active layers (920), and the holes are filled with an isolation material such as oxides or silicon nitride. The plurality of holes are arranged in a first row and a second row. The first row of holes is aligned with the first row of conductive pillars, and the second row of holes is aligned with the second row of conductive pillars.

The substrate is etched using a first etch process to form a plurality of stacks of active strips, a plurality of isolation strips aligned with the stacks, and stacks of contact pads terminating the plurality of active strips at a second end of the plurality of active strips (930).

The substrate, including the plurality of spaced-apart pillars of a first conductor material as precursor formations for forming source lines, is also etched using the first etch process to form a plurality of more narrow conductive pillars (e.g. 421, 422, FIG. 4) aligned with the stacks and between a first end of the plurality of active strips and the plurality of isolation strips (940). The more narrow conductive pillars act as source lines (e.g. 128, FIGS. 1 and 1A).

A layer of memory material is deposited over the plurality of stacks of active strips, and at least on side walls of the active strips (950). The layer of memory material can include multilayer dielectric charge storage structures, and different programmable resistance memory materials.

A body of conductor material is then formed by depositing a second conductor material over the substrate. The body of conductor material is etched using a second etch process to remove the second conductor material from certain areas (960). The removed areas define patterns for the plurality of active strips, the plurality of source lines, the plurality of isolation strips, the stacks of contact pads, word lines, ground select lines and string select gate structures.

The body of conductor material is etched using a third etch process to form the word lines, the ground select lines and the string select gate structures over the plurality of stacks (970). A string select gate structure over a particular stack in the plurality of stacks is isolated from string select gate structures over adjacent stacks in the plurality of stacks.

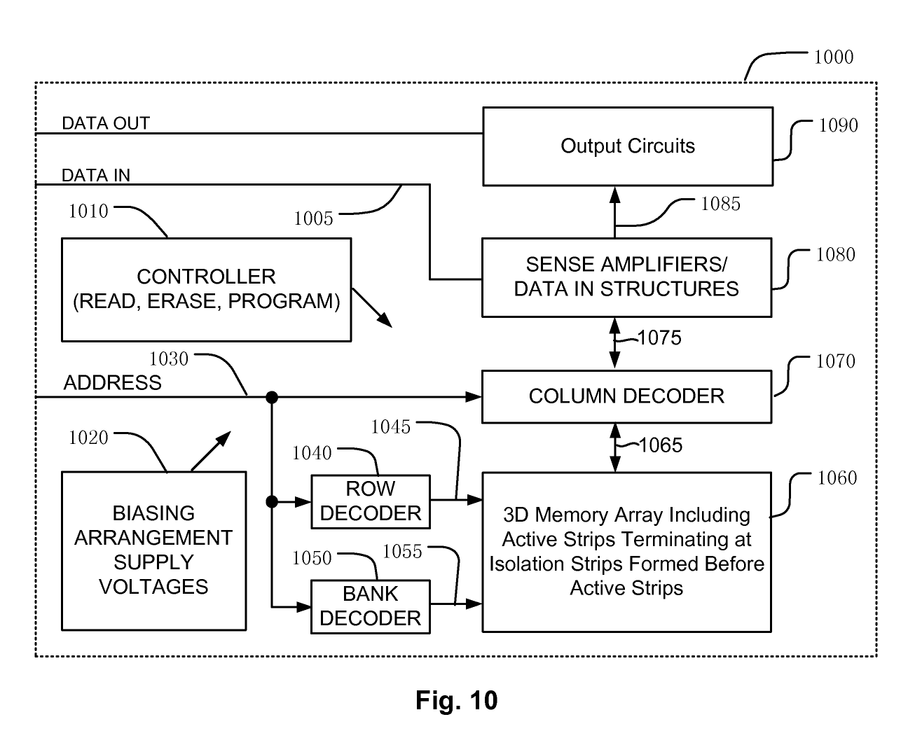

FIG. 10 is a simplified block diagram of an integrated circuit memory device according to an embodiment. The integrated circuit 1000 includes a memory array 1060 on an integrated circuit substrate. The memory array 1060 includes active strips terminating at isolation strips, where the isolation strips are formed before the stacks of active strips and word lines are formed.

A row decoder 1040 is coupled to a plurality of word lines 1045, and arranged along rows in the memory array 1060. A column decoder 1070 is coupled to a plurality of bit lines 1065 arranged along columns in the memory array 1060 for reading and programming data from the memory cells in the memory array 1060. A bank decoder 1050 is coupled to a plurality of banks in the memory array 1060 on bus 1055. Addresses are supplied on bus 1030 to column decoder 1070, row decoder 1040 and bank decoder 1050. Sense amplifiers and data-in structures in block 1080 are coupled to the column decoder 1070, in this example via data bus 1075. Sensed data from the sense amplifiers are supplied via output data lines 1085 to output circuits 1090. Output circuits 1090 drive the sensed data to destinations external to the integrated circuit 1000. Input data is supplied via the data-in line 1005 from input/output ports on the integrated circuit 1000 or from other data sources internal or external to the integrated circuit 1000, such as a general purpose processor or special purpose application circuitry, or a combination of modules providing system-on-a-chip functionality supported by the memory array 1060, to the data-in structures in block 1080.

In the example shown in FIG. 10, a controller 1010 using a bias arrangement state machine controls the application of bias arrangement supply voltage generated or provided through the voltage supply or supplies in block 1020, such as read and program voltages. The controller 1010 can include modes of operation for multi-level cell (MLC) programming and reading. The controller 1010 can be implemented using special-purpose logic circuitry as known in the art. In alternative embodiments, the controller comprises a general-purpose processor, which can be implemented on the same integrated circuit, which executes a computer program to control the operations of the device. In yet other embodiments, a combination of special-purpose logic circuitry and a general-purpose processor can be utilized for implementation of the controller.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A method for manufacturing a semiconductor device, comprising:
providing a substrate having a plurality of active layers;
forming a plurality of holes (BLC holes) through the plurality of active layers; and
filling the plurality of holes with an isolation material (OX seals) to form filled holes,
wherein the plurality of holes is positioned in the plurality of active layers such that a plurality of stacks of active strips can be formed in the plurality of active layers after said filling, and be terminated at the plurality of holes filled with the isolation material.

2. The method of claim 1, wherein the plurality of holes are configured in a row, and including:
using a mask defining a plurality of parallel lines, including lines that cross over respective filled holes in the plurality of holes; and
etching the plurality of active layers and the filled holes using a first etch process, to form the plurality of stacks of active strips terminating with strips of isolation material where the lines crossed over the respective holes.

3. The method of claim 1, wherein the plurality of holes are configured in a first row and a second row, and including:
using a mask defining a plurality of parallel lines, including a first subset of lines that cross over respective filled holes in the first row, and a second subset of lines that cross over respective filled holes in the second row; and
etching the plurality of active layers and the filled holes using a first etch process, to form the plurality of stacks of active strips including a first set of stacks terminating with strips of isolation material where the lines crossed over the respective holes in the first row of holes, and a second set of stacks terminating with strips of isolation material where the lines crossed over the respective holes in the second row of holes.

4. The method of claim 3, including forming select gate structures over stacks of active strips in the first set of stacks between strips of isolation material at which stacks in the second set of stacks terminate.

5. The method of claim 1, wherein the plurality of holes are configured in a first row, including:
forming a plurality of conductive pillars configured in a second row;
using a mask defining a plurality of parallel lines, including lines that cross over respective filled holes in the first row and respective conductive pillars in the second row; and
etching the plurality of active layers, the conductive pillars and the filled holes using a first etch process, to form the plurality of stacks of active strips including strips of more narrow conductive pillars and terminating at strips of isolation material where the lines crossed over the respective holes and conductive pillars.

6. The method of claim 1, comprising:
etching the plurality of active layers and the isolation material in the plurality of holes using a first etch process, to form the plurality of stacks of active strips (BL), and a plurality of isolation strips aligned with the stacks.

7. The method of claim 6, wherein the substrate has a plurality of spaced-apart pillars of a first conductor material extending through and connecting the plurality of active layers, comprising:
etching the plurality of spaced-apart pillars using the first etch process, to form a plurality of more narrow conductive pillars aligned with the stacks and between a first end of the plurality of stacks of active strips (BL) and the plurality of isolation strips.

8. The method of claim 7, comprising:
etching the plurality of active layers using the first etch process, to form stacks of pads (BL pads) terminating the plurality of active strips (BL) at a second end of the plurality of stacks of active strips.

9. The method of claim 8, comprising:
forming a body of conductor material by depositing a second conductor material over the substrate; and
etching the body of conductor material using a second etch process, to remove the second conductor material from areas defining patterns for the plurality of active strips, the plurality of source lines, the plurality of isolation strips, the stacks of pads, word lines, ground select lines and string select gate structures.

10. The method of claim 9, comprising:
etching the body of conductor material using a third etch process, to form the word lines, the ground select lines and the string select gate structures over the plurality of stacks, wherein a string select gate structure over a particular stack in the plurality of stacks is isolated from string select gate structures over adjacent stacks in the plurality of stacks.

11. The method of claim 9, comprising:
forming a layer of memory material on side walls of the active strips in the plurality of stacks before said forming the body of conductor material.

12. A method for manufacturing a semiconductor device, comprising:
providing a substrate having a plurality of active layers;
forming a plurality of holes (BLC holes) through the plurality of active layers including a first row of holes and a second row of holes;
filling the plurality of holes with an isolation material to form filled holes; and
etching the plurality of active layers and the filled holes to form first and second sets of interdigitated stacks of active strips aligned with and terminating at isolation strips, the first set comprising strips extending from pads in a first stack of pads and terminating at isolation strips remaining from corresponding filled holes in the first row, and the second set comprising strips extending from pads in a second stack of pads and terminating at isolation strips remaining from corresponding filled holes in the second row.

13. A semiconductor device, comprising:
a substrate having a plurality of stacks of active strips including first and second sets of interdigitated stacks of active strips; and
a first row of isolation strips and a second row of isolation strips,
wherein active strips in the first set extend from pads in a first stack of pads and are aligned with and terminate at corresponding isolation strips in the first row, and active strips in the second set extending from pads in a second stack of pads and are aligned with and terminate at corresponding isolation strips in the second row.

14. The device of claim 13, comprising a plurality of source line pillars aligned with the stacks and between an end of the plurality of stacks of active strips and one of the first row of isolation strips and the second row of isolation strips.

15. The device of claim 13, comprising word lines, ground select lines and string select gate structures over the plurality of stacks, wherein a string select gate structure over a particular stack in the plurality of stacks is isolated from string select gate structure over adjacent stacks in the plurality of stacks.

16. The method of claim 13, comprising a layer of memory material on side walls of the active strips in the plurality of stacks.

17. A semiconductor device, comprising:
a substrate having a plurality of stacks of active strips including strips of conductive material at an end of the plurality of stacks of active strips; and
a row of isolation strips,
wherein active strips in the plurality of stacks extend from a stack of pads and are aligned with and terminate at the row of isolation strips at the end of the plurality of stacks of active strips with the conductive material.
